(19) United States
(12) Patent Application Publication
(10) Pub. No.: US 2015/0014730 A1
(43) Pub. Date: Jan. 15, 2015

(54) LIGHT-EMITTING DIODE

(71) Applicant: LIMO Patentverwaltungs GmbH & Co. KG, Dortmund (DE)

(72) Inventor: Aleksei Mikhailov, Dortmund (DE)

(73) Assignee: LIMO Patentverwallungs GmbH & Co. KG, Dortmund (DE)

(21) Appl. No.: 14/380,085

(22) PCT Filed: Feb. 22, 2013
(86) PCT No.: PCT/EP2013/053552

§ 371 Date: Aug. 21, 2014

(30) Foreign Application Priority Data
Feb. 24, 2012 (DE) 102012003638.8

(51) Int. Cl. H01L 33/02; H01L 33/00

(52) U.S. Cl. CPC H01L 33/025; H01L 33/0095; H01L 2933/0058
USPC 257/98; 438/29

(57) ABSTRACT

The invention relates to a light-emitting diode comprising a body (1) which consists at least partly of a semiconductor material. The body (1) has an active layer (2), in which light can be generated, and at least one exit face (3) from which the light that is generated in the active layer (2) can exit. A plurality of structures (5) is provided in the body (1), and at least some of the light exiting the active layer (2) can be scattered at said structures before reaching the exit face (3).

The present invention relates to a light-emitting diode according to the preamble of claim 1 and to a method for manufacturing such a light-emitting diode.

A light-emitting diode of the aforementioned type substantially corresponds to the structure of the majority of the currently available light-emitting diodes. Such light-emitting diode according to the prior an is depicted schematically in FIG. 7.

An active layer 12 is arranged inside a body 11 made at least partially of semiconductor materials, in which light is generated. FIG. 7 shows exemplary light beams 13, 14 which in the illustrated example emanate from an arbitrarily selected region of the active layer 12. The light beams 13, 14 emanating from the active layer 12 pass partially through the body 11 to a boundary surface of the body 11 forming an exit face 15. Those light beams 13 exit from the exit face when the angle α, at which the light beam 13 is incident on the inside of this exit face 15, is less than or equal to the critical angle of total reflection of the corresponding material. All other light beams 14 which are incident on the exit face 15 at an angle greater than the critical angle of total reflection are back-reflected by the exit face 15 into the body 11.

As a result, only a very small portion of the light generated in the active layer actually exits from the exit face, so that the light-emitting diode has a low efficiency. To increase the efficiency of light-emitting diode, Tsai, Min-An et al. propose in IEEE Photonics Technology Letters, Vol.22, No. 1, published on Jan. 1, 2010, to provide the outer side of the exit face with a biomimetic structure. This biomimetic structure has a plurality of approximately conical elevations with rounded tip. With the biomimetic structure, light beams that are oriented at a comparatively large angle in the direction of the exit face can in some cases pass through the exit face. Nevertheless, a majority of the light is reflected back by the exit face into the body of the light-emitting diode and reaches the region of the exit face only after many reflections on the other interior sides of the body. This also causes a comparatively low efficiency of the light-emitting diode, because portions of the light can be absorbed on the long paths through the body.

The object underlying the present invention is to provide a light-emitting diode of the aforementioned type that is more efficient. Furthermore, a method for manufacturing such a light-emitting diode is to be provided.

This is attained with the invention with respect to the light-emitting diode with a light-emitting diode of the aforementioned type having the characterizing features of claim 1 and with respect to the method by a process of the aforementioned type having the characterizing features of claim 8 or of claim 10. The dependent claims relate to preferred embodiments of the invention.

According to claim 1, a plurality of structures may be arranged in the body on which at least portions of the light emanating from the active layer may be scattered before impinging on the exit face. In this way, light beams propagating at unfavorable angles can be scattered before impinging on the exit face, so that a portion of these light beams can exit from the exit face.

The plurality of structures provided in the body may eb disposed in at least one scattering layer or in at least one scattering region. The light can then freely spread in a relatively large region of the body, wherein only a defined region. such as a layer, or a differently shaped region, or several layers or several differently shaped regions contribute to scattering of the light beams.

The at least one scattering layer may be oriented parallel to the active layer and/or to the exit face. Such a structure causes the light to exit the exit face with a relatively uniform distribution.

Specifically, the exit face gay of course be aligned parallel to the active lay

The thickness of he at least one scattering layer may be between 1 μm and 10 μm.

The body provided in the plurality of structures may be disposed between the active layer and the at least one exit face. Alternatively, the plurality of structures provided in the body may be arranged on the side of the active layer facing away from the at least one exit face. The structures provided in the body may also be arranged between the active layer and the at least one exit face as well as on the side of the active layer facing away from the at least one exit face.

The size of the individual structures may be between 1 μm and 10 μm.

According to claim , the method is characterized by the following process steps:
The body of the light-emitting diode is produced by an epitaxial process;
After the production of the body, the body is irradiated with the laser light to generate in the body a plurality of structures.

This process has the advantage that the light-emitting diode can be manufactured using standard manufacturing processes, which do not need to be modified to produce the structures. Instead, these structures can be generated in a subsequent process step, wherein the location, the size and the number of structures can be relatively freely selected by adjusting optical parameters.

The laser light may be focused so that the focal plane is arranged in the interior of the body. In this way, the exit face is not damaged by the laser radiation used to generate the structures. Furthermore, the focal plane can be positioned inside the body so that the active layer is also not damaged by the laser radiation used to generate the structures.

According to claim 10, the method is characterized by the following process steps:
The body of the light-emitting diode is produced by an epitaxial process:
While the epitaxial process is performed, a plurality of structures is generated in the body of the light-emitting diode.

This process has the advantage that the structures are generated during the manufacturing process of the light-emitting diode, so that no subsequent process steps need to be performed.

Other features and advantages of the present invention will be apparent from the following description of preferred exemplary embodiments in conjunction with the accompanying drawings, which show in:

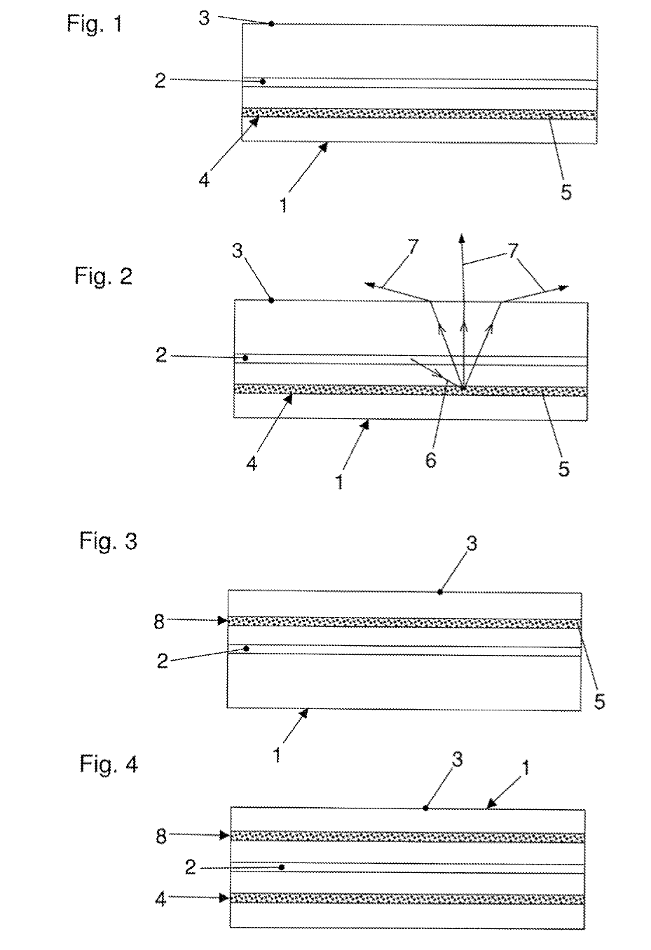

FIG. 1 a schematic sectional view of a first embodiment of a light-emitting diode according to the invention;

FIG. 2 an exemplary optical path in the light-emitting diode according to FIG. 1;

FIG. 3 a schematic sectional view of a second embodiment of a light-emitting diode according to the invention;

FIG. 4 a schematic sectional view of a third embodiment of a light-emitting diode according to the invention;

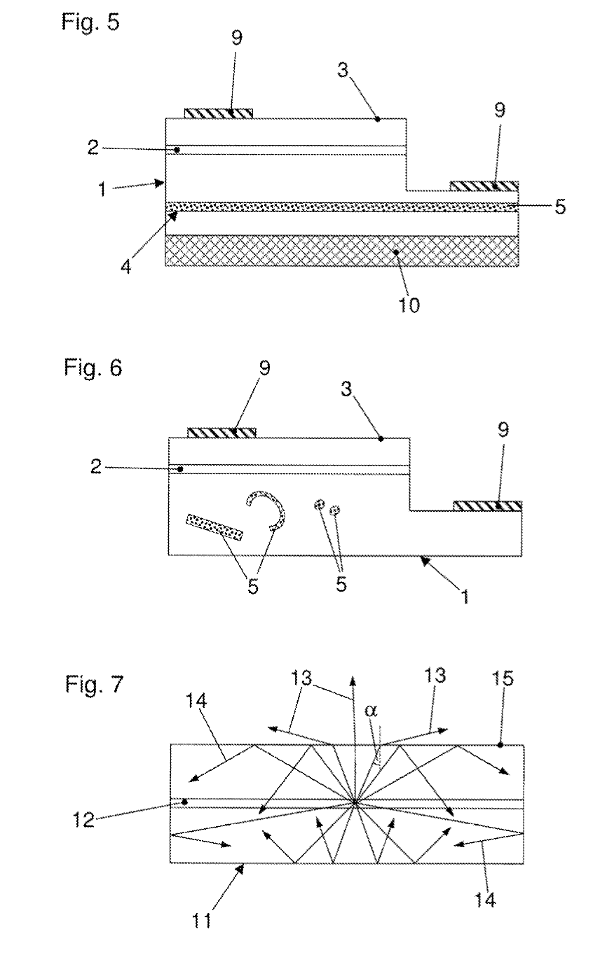

FIG. 5 a schematic sectional view of a fourth embodiment of alight-emitting diode according to the invention;

FIG. 6 a schematic sectional view of a fifth embodiment of a light-emitting diode according to the invention;

FIG. 7 a schematic sectional view of a light-emitting diode according to the prior art.

In the figures, identical or functionally identical parts or light beams are indicated by the same reference symbols.

The schematic diagrams of FIGS. 1 to 6 show a light-emitting diode with a body 1 which is at least in part composed of semiconductor materials. The body 1 has in particular the form of a cuboid. An active layer 2 in which the light is generated is disposed inside the body 1. The body 1 furthermore includes an exit face 3, which in the illustrated exemplary embodiment is the top surface of the cuboid-shaped body 1. In particular, the active layer 2 is arranged parallel to and spaced from the exit face 3.

FIG. 5 shows in form of an example a substrate 10 disposed underneath the body 1, which may be composed, for example, of sapphire. Such substrate is optional, but may also be provided in the other embodiments shown in FIG. 1 to FIG. 4 and FIG. 6.

The body 1 of FIG. 1 further includes a scattering layer 4 in which a plurality of structures 5 is provided, on which at least portions of the light emanating from the active layer 2 can be scattered before impinging on the exit face 3. In the exemplary embodiment illustrated in FIG. 1 and FIG. 2, the scattering layer 4 is arranged on the side of the active layer 2 facing away from the exit face 3 and spaced apart therefrom. The thickness of the scattering layer 4 can, for example, be between 1 μm and 10 μm.

In the illustrated exemplary embodiment, the scattering layer 4 is oriented parallel to the active layer 2. However, the scattering layer 4 may also be oriented with respect to the active layer 2 at an angle different from 0°.

FIG. 2 shows by way of example a light beam 6 which extends from the active layer 2 downward or in a direction that faces away from the exit face 3. FIG. 2 illustrates that the light beam 6 can be at least partly scattered on the structures 5 so that light beams 7 or sub-beams extend from these structures 5 upward to the exit face 3 and are hence at least partly incident on the inside of the exit face 3 at angles that are smaller than or equal to the critical angle for total reflection of the corresponding material. FIG. 2 shows three light beams 7 for which this is the case and which therefore exit through the exit face 3.

The size of the individual structures can be between 1 μm and 10 μm. In particular, the structures can be formed by defects and lattice defects.

FIG. 3 shows that a scattering layer 8 with scattering structures 5 is arranged between the active layer 2 and the exit face 3 instead of on the side of the active layer 2 facing away from the exit face 3.

The exemplary embodiment of FIG. 4 illustrates that, on the one hand, a scattering layer 4 may be arranged on the side of the active layer 2 facing away from the exit face 3 and, on the other hand, a scattering layer 8 may be arranged between the active layer 2 and the exit face 3.

Several spaced-apart scattering layers may also be arranged on the side of the active layer 2 facing away from the exit face 3 and/or between the active layer 2 and the exit face 3.

FIG. 5 illustrates by way of example two electrodes 9, which are used to apply a voltage to the light-emitting diode. In the other embodiments, similarly formed or positioned electrodes 9, or differently formed or positioned electrodes, may be provided.

It is evident in the embodiment of Fig, 5 that the active layer 2 is disposed in the vertical direction at a height located between the two electrodes 9. Conversely, the scattering layer 4 is arranged in a region which in the vertical direction is not located between the two electrodes, so that no current flows through the scattering layer.

Instead of a scattering layer 4 with scattering structures 5, other scattering regions, such as cylindrical regions, stripe-shaped regions, lens-shaped regions or regions having other shapes may be provided with scattering structures 5. FIG. 6 shows instead of a scattering layer several other forms of scattering regions with scattering structures 5.

A light-emitting diode according to the invention may be manufactured by producing the body 1 of the light-emitting diode with an epitaxial process without a scattering layer 4, 8 and/or without scattering structures 5. The body 1 can then be exposed to laser radiation either immediately thereafter or at a later time so as to produce in the body 1 a plurality of structures 5.

For this purpose, a high-power laser can be used, which can be implemented for example as a femtosecond laser. The laser radiation of this laser can be shaped, in particular homogenized and focused, using suitable micro-optical elements.

For example, a line-shaped intensity distribution care be generated in this way that can be scanned or moved in a direction perpendicular to the extent of the line, so that thereby the focus or the region of greatest intensity sweeps across an area.

The laser light may be focused so that the focal plane is located or is formed inside the body 1 by scanning. The exit face 3 is then not damaged by the laser radiation used to produce the structures 5. Furthermore, the focal plane can be positioned inside the body 1 such that the active layer 2 is also not damaged by the laser radiation used to produce the structures 5.

In particular, the laser radiation used to produce the structures 5 can generate the above-mentioned defects and lattice defects. To produce the scattering structures, the laser radiation may have a power density that is greater or smaller than that power density that corresponds to a typical fracture stress of the material of the body 1.

1-10. (canceled)

11. A light-emitting diode, comprising
a body (1) composed at least partially of a semiconductor material, wherein the body (1) has an active layer (2) in which light is generated, and at least one exit face (3) from which the light generated in the active layer (2) exits, wherein a plurality of structures (5) is provided in the body (1) on which at least portions of the light emanating from the active layer (2) are scattered before impinging on the exit face (3).

12. The light-emitting diode according to claim 11, wherein the plurality of structures (5) provided in the body (1) is disposed in at least one scattering layer (4, 8) or in at least one scattering region.

13. The light-emitting diode according to claim 12, wherein the at least one scattering layer (4, 8) is oriented parallel to the active layer (2) and/or the exit face (3),

14. The light-emitting diode according to claim 12, wherein the at least one scattering layer (4, 8) has a thickness of between 1 μm and 10 μm.

15. The light-emitting diode according to claim 11, wherein the plurality of structures (5) provided in the body (1) is disposed between the active layer (2) and the at least one exit face (3).

16. The light-emitting diode according to claim 11, wherein the plurality of structures (5) provided in the body (1) is disposed on a side of the active layer (2) facing away from the at least one exit face (3).

17. The light-emitting diode according to claim 11 wherein the size of the individual structures (5) is between 1 μm and 10 μm.

18. A method for producing a light-emitting diode of claim 11, comprising the following steps:
producing a body (1) of the light-emitting diode by an epitaxial process;
irradiating the body (1) with laser light to generate in the body (1) a plurality of structures (5).

19. The method according to claim 18, further comprising the step of:
focusing the laser light so that the focal plane is disposed in the interior of the body (1).

20. A method for producing a light-emitting diode of claim 11, comprising the following steps:
producing the body (1) of the light-emitting diode by an epitaxial process;
generating in the body (1) of the light-emitting diode a plurality of structures (5) during the epitaxial process.
